(19) United States
(12) Patent Application Publication
(10) Pub. No.: US 2007/0200547 A1
(43) Pub. Date: Aug. 30, 2007

(54) Object detector

(76) Inventor: Ming Chen, Nanjing (CN)

Correspondence Address: MCDERMOTT, WILL & EMERY LLP, 227 WEST MONROE STREET, CHICAGO, IL, 60606-5096, US

(21) Appl. No.: 11/710,712

(22) Filed: Feb. 26, 2007

(30) Foreign Application Priority Data
Feb. 28, 2006 (CN) 200620069685.6

(51) Int. Cl. G01R 19/00

(52) U.S. Cl. 324/67

(57) ABSTRACT

An object of the present invention is to provide an object detector which can intuitively show detection information and facilitate the observation of a detected surface covered by a display screen. The detector includes a housing, a detecting circuit for detecting a hidden object behind a surface, which is arranged in the housing and includes at least one detecting element, a power supply electrically connected to the detecting circuit, and a display device 10 electrically connected to the detecting circuit, which includes a display screen attached to the housing. The display screen is transparent in a non-display stat while an information-displaying section of the display screen is opaque in a display state. By using such an object detector, an operator can obtain an intuitive indication from the object detector and simultaneously observe the marking condition on a section of a detected surface covered by a display screen during a detection operation.

### CROSS-REFERENCE TO RELATED APPLICATIONS

This application claims priority to Chinese Application No. 200620069685.6 filed Feb. 28, 2006, the entire disclosure of which is incorporated herein by reference. Priority to this application is claimed under 35 U.S.C. 119, 120 and/or 365.

### FEDERALLY SPONSORED RESEARCH OR DEVELOPMENT

Not Applicable.

### TECHNICAL FIELD

The present invention relates to an object detector, and more particularly to an object detector for detecting an object hidden behind a surface.

### DESCRIPTION OF PRIOR ART

Generally, if an object of substantial weight is to be hung or fixed on a wall or other similar surfaces, it is preferable to hang or fix the object to a stud hidden behind the wall or other similar surfaces by a fixing device, such as screws. Furthermore, during construction or indoor decoration, it is necessary to avoid destroying live electrical wires, and other lines, which are hidden in the walls. So, it is necessary to accurately locate and distinguish between these objects hidden in the walls or behind the other similar surfaces during construction or indoor decoration.

Currently, an object detector satisfying the above needs has been developed that can help operators accurately locate and distinguish between the above objects. For example, an object detector of this type can detect and identify wooden stud, metal bars, live wires, pipelines, water pipes or other objects hidden in walls or behind other similar surfaces. The existing object detector usually has an indicating mark on its housing. If it detects a certain object, the detector makes a buzzing sound or lights an indicator lamp to alert an operator, where the sound or lamp corresponds to the object type. And at the moment, the indicating mark is located on an edge or in the middle of the detected object. However, such an indication isn't sufficiently intuitive. If there is a sign marked on the surface to be detected, the operator can't see the sign on the hidden section of the detected surface covered by the object detector. It further needs an additional light source to provide assistant lighting for a detecting operation in an obscure environment, which brings great inconvenience to the detecting operation.

### SUMMARY OF THE INVENTION

An object of the present invention is to provide an object detector, which can intuitively show detection information and can facilitate the observation of a portion of a detected surface covered by a display screen.

Another object of the present invention is to provide a self-illuminating object detector, to help operators in performing a detecting operation in an obscure environment successfully.

To achieve the above objects, an object detector for detecting an object hidden behind a surface according to the present invention includes a housing, a detecting circuit which detects the hidden object behind a surface and that is arranged in the housing and includes at least one detecting element, a power supply electrically connected to the detecting circuit, and a display device 10 electrically connected to the detecting circuit. The display device 10 includes a display screen connected to the housing. The display screen is transparent in a non-display state, while an information-displaying section of the display screen is opaque in a display state.

The opaque information-displaying section of the display screen is in an illuminating state when the object detector is in a display state.

By using an object detector according to the present invention, an operator can obtain an intuitive indication from the object detector and simultaneously observe the marking condition on a covered section of a detected surface by the display screen during a detecting operation. Furthermore, the object detector according to the invention facilitates use in an obscure environment.

### BRIEF DESCRIPTION OF THE DRAWINGS

To understand the present invention, it will now be described by way of example, with reference to the accompanying drawings in which:

FIG. 1 is a plan view of the object detector of the invention, showing the detector in a display condition wherein a wooden object, obscured behind a surface, is recognized by the object detector;

FIG. 2 is a plan view of the object detector, showing the detector in a display condition wherein an obscured metallic object is recognized by the object detector;

FIG. 3 is a plan view of the object detector, showing the detector in a display condition wherein an obscured wire is recognized by the object detector;

FIG. 4 is a plan view of the object detector, showing the detector in a first display condition wherein an obscured object is recognized by the object detector;

FIG. 5 is a plan view of the object detector, showing the detector in a second display condition wherein the obscured object is recognized by the object detector; and

FIG. 6 is a plan view of the object detector, showing the detector in a third display condition wherein the obscured object is recognized by the object detector.

### DETAILED DESCRIPTION

The present invention is not intended to be limited to the above-mentioned embodiment. It is easily understood for those ordinary skilled in the art that there are also various modifications or alternatives without departing the conception and principle of the present invention. The scope of the present invention is defined by the appended claims.

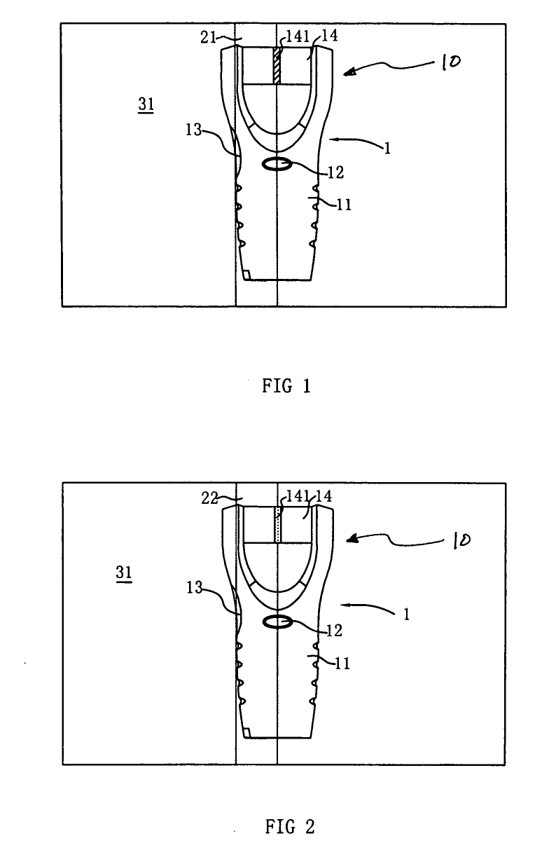

FIGS. 1-3 show an object detector 1 according to one preferred embodiment of the present invention. The object detector 1 includes a housing 11, a calibration/detection button 13, a calibration/detection indicator lamp 12 and a display device 10. The calibration/detection indicator lamp 12 is arranged in the middle of a front surface of the housing 11. The calibration/detection button 13 is arranged on a lateral surface of the housing 11 and is convenient for holding by an operator.

The object detector 1 further includes an object-detecting circuit (not shown) arranged within the housing 11. U.S. Pat. No. 4,099,118 discloses a detecting circuit using a pair of capacitive plates as detecting elements. It will be indicated that an object has been detected when the detecting circuit detects a change in dielectric constant of a wall at a certain position on the wall (namely when there is an object, the material of which is different from the wall material, at this position). U.S. Pat. No. 4,464,622 improves the detecting circuit in U.S. Pat. No. 4,099,118 for detecting live wires. U.S. Pat. No. 6,215,193 discloses a detecting circuit, which uses capacitive plates as detecting elements for wooden objects, an electromagnetic induction circuit as the detecting element for metal objects, and a passive antenna as the detecting element for live wires. Moreover, U.S. Pat. No. 5,352,974, No. 5,619,128, No. 5,917,314, No. 6,023,159 and No. 6,894,508 disclose other embodiments of the detecting circuit. The contents of the above U.S. patents are incorporated herein. The contents of the above patents are disclosed in the respective patent documents, so they need not be further described herein.

The object detector 1 further includes a power supply (not shown) connected electrically to the detecting circuit. Preferably, the power supply is one or more dry batteries arranged in the housing 11. It is conceivable for a skilled person in this art to use other kinds of power supplies for the object detector.

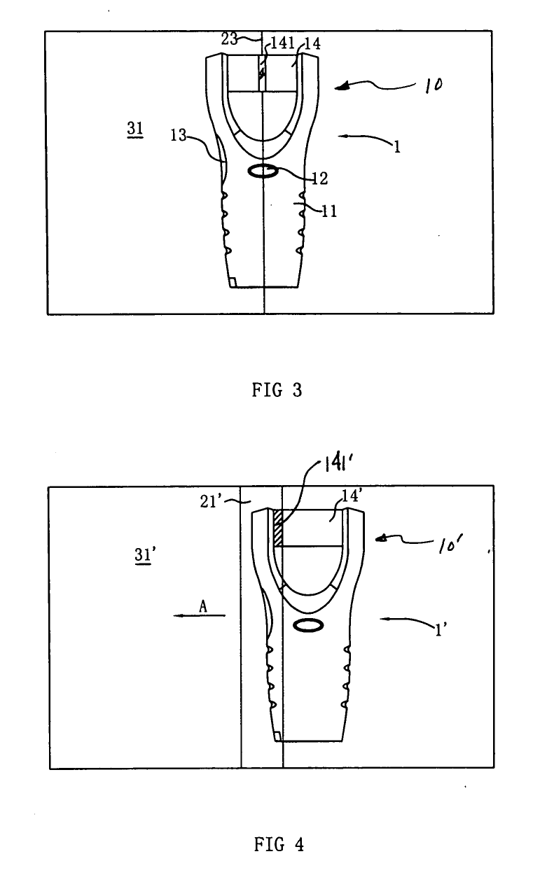

The display device 10 of the object detector 1 includes a display screen 14. The display device 10 is electrically connected to the detecting circuit for receiving the detection signals from the detecting circuit, and then displays a corresponding pattern or patterns on the display screen 14. The display screen 14 is attached on a front end of the housing 11. In a non-display state, the display screen 14 is transparent so that the operator can see the detected surface covered by the display screen 14 therethrough. In a display state, a information-displaying section of the display screen 14 is opaque, while the rest of the screen without display information remains transparent. In this embodiment, the entire display screen 14 is transparent when no object behind the wall 31 is detected, and a portion or section 141 of the display screen 14 turns opaque and displays a pattern corresponding to the object kind when an object behind the wall 31 is detected. Thus, the display screen 14 includes at least one indicating section or portion 141 that provides a visible signal to indicated the detection of an object behind a surface 31, while the remaining portion of the screen 14 remains transparent as the detector 1 is moved along the surface 31. As shown in FIG. 1 and FIG. 2, for example, the section 141 of the display screen 14 turns opaque and displays an edge of the wooden or metal object with a different pattern when a wooden object 21 or a metal object 22 behind the wall 31 is detected. Also as shown in FIG. 3, the section 141 of the display screen 14 displays a pattern representing a live wire 23 behind wall surface 31 so as to indicate the position of the wire 23. The display device 10 could show not only the position of edges of the detected object but also the position of other portions of the detected object, which could be displayed by the indicator section(s) 141 with patterns and/or texts. With a display device 10 of this type, an operator can observe the conditions of the detected wall covered by the display screen through the remaining transparent section of the display screen. It is particularly applicable, if there are other signs on the section of the wall covered by the display screen.

When it is needed to carry out a detection operation, an operator generally places the detector 1 on the wall with one hand and then presses the calibration/detection button with his thumb. When the calibration/detection lamp 12 turns from a first color, such as yellow, to a second color, such as green, to indicate that an calibration process has been completed, the operator moves the detector 1 in a direction perpendicular to the longitudinal axis of the detector 1, and a corresponding pattern or text is displayed on the display screen when an object hidden behind the wall is detected.

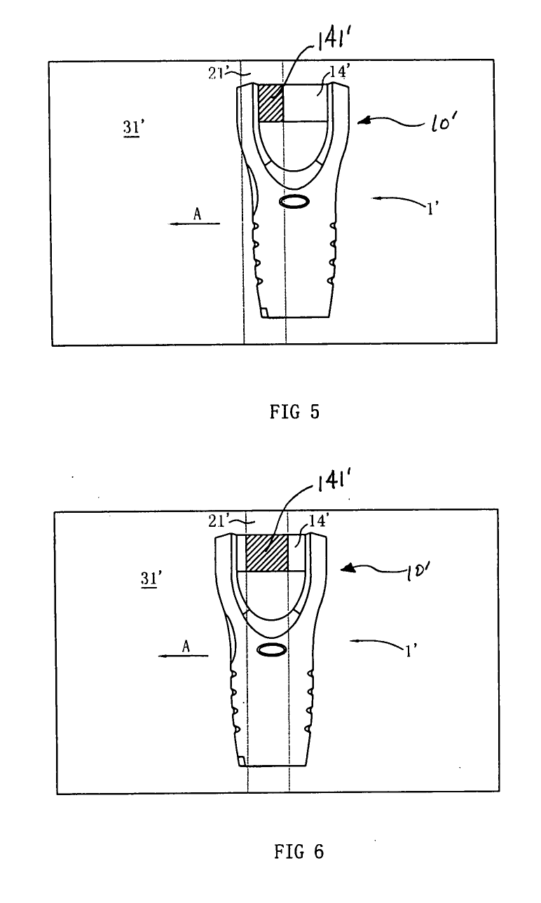

The display device 10 is also constructed to dynamically display the position variation of the detected object relative to the object detector 1 along with the movement of the detector 1 along the surface 31′. As shown in FIGS. 4-6, in another embodiment of the present invention, the position of the two edges of the detected object 21′ relative to the object detector 1 is dynamically displayed on the display screen 14′ with the gradual movement of the detector 1′ on the wall 31′ in the direction A. The configuration and position of the indicating sections 141′ with respect to the display screen 14′ varies with the movement of the detector 1. The patterns corresponding to other kinds of objects detected by the object detector and other information of the object detector, such as a calibration/detecting state, could also be displayed via the display device 10 according to different desires.

In another embodiment of the present invention, the indicating section 141 of the display screen 14 can self-illuminate in the display state so that the object detector 1 can be used in a low-light environment, without the use of a background or supplemental light source.

The above embodiments are only intended to explain the design and the principle of the present invention, but not to limit the invention. For an ordinary skilled person in the art, it is apparent that in addition to the above preferred embodiments, there are also many other substituted and modified embodiments within the scope of the present invention. The scope of protection of the present invention is defined by appended claims.

What is claimed is:

1. An object detector for detecting an object residing behind a surface, the object detector comprising:
a housing having an object-detecting circuit, a power supply electrically connected to the object-detecting circuit; and a display device electrically connected to the detecting circuit, the display device including a display screen;
wherein the display screen is transparent in a non-display state, and wherein a section of the display screen turns opaque in a display state to indicate the detection of an object.

2. The object detector of claim 1, wherein in the display state, the opaque section of the display screen is illuminated.

3. The object detector of claim 1, wherein in the display state, the remaining portion of the display screen is transparent.

4. The object detector of claim 3, wherein in the display state, the remaining portion of the display screen not illuminated.

5. The object detector of claim 1, the housing including a multi-function button with a calibration feature, and wherein the button is depressed prior to using the object detector.

6. The object detector of claim 5, wherein the multi-function button includes a detection feature, wherein the button is depressed during use to detect an object residing behind the surface.

7. The object detector of claim 5, wherein the power supply includes at least one battery.

8. An object detector for dynamically detecting an object residing behind a surface, the object detector comprising:
a housing having an object-detecting circuit and a power supply electrically connected to the object-detecting circuit;
the housing further having a display device that receives detection signals from the detecting circuit, the display device including a display screen with a section that displays a first visual indicator to indicate the detection of an object residing behind a surface to which the object detector is applied, and wherein the remaining portion of the display screen is transparent to allow an operator to view the surface.

9. The object detector of claim 8, wherein the first visual indicator displayed by the screen section corresponds to a first edge of the detected object.

10. The object detector of claim 9, wherein the screen section displays a second visual indicator that corresponds to a second edge of the detected object.

11. The object detector of claim 8, wherein the first visual indicator displayed by the screen section is a first pattern corresponding to a first type of detected object.

12. The object detector of claim 11, wherein the screen section displays a second visual indicator that is a second pattern corresponding to a second type of detected object.

13. The object detector of claim 8, wherein in a non-display state, the entire display screen is transparent to allow the operator to view the surface.

14. The object detector of claim 8, wherein the housing further includes a calibration and detection button operably connected to the object-detecting circuit.

15. An object detector for detecting the presence and the position of an object residing behind a surface, the object detector comprising:
a housing having an object-detecting circuit and a power supply electrically connected to the object-detecting circuit;
the housing further having a display screen that receives detection signals from the detecting circuit, the display screen having a plurality of indicating sections that provide a visible signal to indicate the detection of an object residing behind a surface; and,
wherein the objector detector is moved along the surface between a first position where a first indicating section of the display screen provides a visible signal to indicate the presence of the object, and a second position where a second indicating section of the display screen provides a visible signal to indicate the presence of the object.

16. The object detector of claim 15, wherein the object detector is moved to a third position where a third indicating section of the display screen provides a visible signal to indicate the presence of the object.

17. The object detector of claim 15, wherein in either of the first or second positions, the remaining portion of the display screen is transparent to allow the operator to view the surface.

18. The object detector of claim 15, wherein the indicating sections display a pattern corresponding to the type of detected object.

19. The object detector of claim 15, wherein the visible signal provided by the indicating sections is an opaque segment that corresponds to the dimensions of the detected object.

20. The object detector of claim 15, wherein when an object is not detected, the entire display screen is transparent to allow the operator to view the surface through the display screen.
